(19) United States
(12) Patent Application Publication
(10) Pub. No.: US 2025/0271481 A1
(43) Pub. Date: Aug. 28, 2025

(54) SELF-CALIBRATING HIGH ACCURACY RADIO FREQUENCY POWER SENSOR

(71) Applicant: Bird Technologies Group Inc., Solon, OH (US)

(72) Inventors: Amr ABDELMONEM, Northbrook, IL (US); Martin DUMMERMUTH, Chagrin Falls, OH (US); Timothy HOLT, Chardon, OH (US); Daniel HOSHIKO, University Heights, OH (US); Jeffrey KLIS, Chardon, OH (US); Melvin HOLT, JR., Cleveland Heights, OH (US)

(73) Assignee: Bird Technologies Group Inc., Solon, OH (US)

(21) Appl. No.: 19/192,341

(22) Filed: Apr. 29, 2025

Related U.S. Application Data
(63) Continuation of application No. PCT/US2025/017211, filed on Feb. 25, 2025.
(60) Provisional application No. 63/558,104, filed on Feb. 26, 2024.

(51) Int. Cl. G01R 29/08; G01R 35/00

(52) U.S. Cl. CPC G01R 29/0878; G01R 35/005

(57) ABSTRACT

Disclosed is a radio frequency (RF) power sensor having measurement uncertainty of less than about ±0.3%, with the ability to adjust its own calibration to maintain its accuracy over time and changing environmental conditions, by means of a suite of environmental and condition-monitoring sensors that are correlated through a model of the power sensor to the behavior of multiple measurement channels in the presence of a wide range of environmental conditions and customer use-cases. The model can incorporate one or more of artificial intelligence, machine learning, neural network, and/or large data model.

### CROSS-REFERENCE TO RELATED APPLICATION

This application is a continuation of International Patent Application No. PCT/US2025/017211, filed on Feb. 25, 2025, which claims the priority benefit of U.S. Provisional Application No. 63/558,104, filed on Feb. 26, 2024, and entitled “SELF-CALIBRATING HIGH ACCURACY RADIO FREQUENCY POWER SENSOR”, all of which are herein incorporated by reference in their entireties.

### FIELD OF THE INVENTION

This application is directed to radio frequency (RF) power measurement. More specifically, to an in-line RF power sensor.

### BACKGROUND OF THE INVENTION

Accuracy of RF power measurement is extremely important, especially in sensitive applications such as semiconductor fabrication.

### BRIEF SUMMARY OF THE INVENTION

According to one aspect of the present invention, a radio frequency (RF) power sensor is provided having a total uncertainty of less than about ±0.3%.

According to one aspect of the present invention, the RF power sensor uses the principle of error reduction by cross-correlation. It is widely understood that the uncertainty of a measurement can be reduced by the square root of N, where N is the number of uncorrelated measurements of the same information. By using N uncorrelated measurements, the uncertainty of the RF power sensor can be reduced.

According to one aspect of the present invention, the RF power sensor achieves this cross-correlation by means of two or more independent measurements of RF power. These measurements are made with the use of independent coupling structures, detectors, and digitizers to achieve the highest degree of independence.

According to one aspect of the present invention, environmental sensors such as temperature, humidity, shock, orientation, and vibration are used to monitor the environment of the RF power sensor. The outputs of these environmental sensors are correlated with changes to the RF power measurements due to the environment and can be used to correct those measurements.

According to one aspect of the present invention, the operating conditions of the RF power sensor are continuously monitored to correct for aging and drift mechanisms that are related to the total time the sensor is powered, the total time that RF power is present, the amplitude of applied RF power, and the number of connector mating cycles.

According to one aspect of the present invention, the environmental and operating conditions are continuously monitored, regardless of whether the RF power sensor is plugged in to external power, by means of a battery-operated monitoring system that operates at all times. This allows for conditions to be monitored even when the unit is being shipped to or from the factory, being handled, and/or in storage.

According to one aspect of the present invention, an algorithm, including, but not limited to, one or more of artificial intelligence, machine learning, neural networks, and large data models are used to create the correlation between the changing environment and the drift mechanisms of the RF power measurements. These techniques are used to inform the sensor of how to adjust its calibration data in order to maintain its specified accuracy (uncertainty) over a wide range of environmental conditions and customer use-cases.

According to one aspect of the present invention, the RF power sensor maintains a user-specified measurement offset from real measured power in order to give the user the ability to offset the measurement for a particular application.

According to one aspect of the present invention, multiple self-calibrating sensors share their calibration data, large data models, or measurement offsets with each other via wired or wireless communication channels.

According to another aspect of the invention, the power sensor uses a vast network of sensors to understand the sensor's environment (temperature, humidity, shock, vibration, orientation, connector activity, RF activity, time).

According to a further aspect of the invention, the power sensor the power sensor has a network of sensors powered with battery backup such the network of sensors can continuously monitor, regardless of whether the power sensor is externally powered or not. This allows the power sensor to monitor its environment during shipping, handling, and storage, which are often the times when the harshest environmental conditions are encountered, but are also times when it is unfeasible to externally power the power sensor.

According to another aspect of the invention, the power sensor collects large amounts of data to establish correlations between the measurements (e.g., between the RF power measurements and all the environmental measurements).

According to another aspect of the invention, the power sensor may use advanced algorithms (e.g. large data models, neural networks, etc.) to correct the RF power measurements and/or modify the existing calibration data for the specific environmental condition, or any environmental conditions that was encountered since the original calibration was performed.

According to an exemplary embodiment of the invention, a radio frequency (RF) power sensor is provided having the ability to adjust its own calibration. According to one aspect of the present invention, the power sensor adjusts its own calibration to maintain a measurement uncertainty of less than about ±3% of power on a transmission line of the power sensor. According to a further aspect of the present invention, the power sensor adjusts its own calibration to maintain a measurement uncertainty of less than about ±1% of power on a transmission line of the power sensor. According to another aspect of the invention, the power sensor adjusts its own calibration to maintain a measurement uncertainty of less than about ±0.5% of power on a transmission line of the power sensor. According to an additional aspect of the invention, the power sensor adjusts its own calibration to maintain a measurement uncertainty of less than about ±0.3% of power on a transmission line of the power sensor.

According to one aspect of the invention, the power sensor uses a model of the power sensor to adjust its own calibration by applying at least one calibration offset, based on correlations between a power measurement of the power sensor and at least one of an environmental condition of the power sensor and/or an operating condition of the power sensor. According to a further aspect of the power sensor, the model uses at least one or more of artificial intelligence, machine learning, neural networks, and/or large data model. According to another aspect of the power sensor, the environmental condition of the power sensor includes at least one or more of temperature, humidity, shock, orientation, and/or vibration; and/or wherein the calibration offset is a calibration offset applied to a forward power measurement of the power sensor and/or a calibration offset applied to a reflected power measurement of the power sensor.

According to an additional aspect of the power sensor, the operating condition of the power sensor includes at least one or more of a total time the power sensor has received external power, a total time the power has been present on the transmission line of the power sensor, a peak amplitude of the power on the transmission line, an average amplitude of the power on the transmission line, a frequency of the power on the transmission line, and/or a number of times a connector of the transmission line has been mated.

According to one aspect of the power sensor, one or both of the operating conditions and the environmental conditions are continuously monitored. According to a further aspect of the invention, the power sensor further comprises an on-board power source that permits a continuous monitoring of the operating conditions and the environmental conditions during shipping, handling, and storage of the power sensor. According to another aspect of the invention, the on-board power source permits the continuous monitoring of the operating conditions and the environmental conditions, when off-board power is not available.

According to an additional aspect of the invention, the calibration is adjusted by applying one or more calibration offsets to the power measurement of the power sensor, wherein the calibration offsets includes one or more user-specified offsets.

According to one aspect of the invention, the power sensor sends shared data to and receives shared data from other power sensors, and uses the shared data received from other power sensors to update the model. According to a further aspect of the power sensor, the shared data includes at least one of calibration data, the calibration offsets applied to the power measurements, the model, the user-specified offsets, and/or data used by the model to generate the calibration offsets. According to another aspect of the invention, the power sensor is an in-line power sensor and has power handing greater than or equal to 1 watt.

According to another exemplary embodiment of the invention, a method for making an radio frequency (RF) power measurement including: providing an RF power sensor having a transmission line and a measurement uncertainty; adjusting a calibration of the power sensor by applying a calibration offset based on a model of the power sensor, an output of at least one environmental sensor of the power sensor, and an output of at least one operating condition sensor of the power sensor; and making a power measurement of RF power on the transmission line using the power sensor after the adjustment of the calibration; wherein the adjustment of the calibration is performed by the power sensor and permits the power sensor to maintain the measurement uncertainty over time and changing environmental conditions.

According to one aspect of the method, the measurement uncertainty is less than about ±3%. According to a further aspect of the method, the measurement uncertainty is less than about ±1%. According to another aspect of the method, the measurement uncertainty is less than about ±0.5%. According to an additional aspect of the method, the measurement uncertainty is less than about ±0.3%.

According to one aspect of the method, the model uses at least one or more of artificial intelligence, machine learning, neural networks, and/or large data model. According to a further aspect of the method, the environmental sensor monitors at least one or more environmental condition, wherein the environmental condition includes at least one or more of temperature, humidity, shock, orientation, and/or vibration; and/or wherein the calibration offset is a calibration offset applied to a forward power measurement of the power sensor and/or a calibration offset applied to a reflected power measurement of the power sensor.

According to a further aspect of the method, the operating condition sensor monitors at least one or more of a total time the power sensor has received external power, a total time the power has been present on the transmission line of the power sensor, a peak amplitude of the power on the transmission line, an average amplitude of the power on the transmission line, a frequency of the power on the transmission line, and/or a number of times a connector of the transmission line has been mated.

According to another aspect, the method further comprises continuously monitoring at least one of the operating conditions and the environmental conditions using the operating conditions sensor and the environmental conditions sensor. According to an additional aspect, the method further comprises using an on-board power source to continuously monitor the operating conditions and the environmental conditions during shipping, handling, and storage of the power sensor. According to one aspect of the method, the on-board power source permits the continuous monitoring of the operating conditions and the environmental conditions, when off-board power is not available. According to a further aspect, the method further comprising applying a user-specified offset to the power measurement.

According to another aspect, the method further comprising sending shared data to and receiving shared data from other power sensors, and updating the model using the shared data received from the other power sensors, the operating conditions, the environmental conditions, the power measurement, and/or the user-specified offset. According to an additional aspect, the shared data includes at least one of calibration data, the corrections applied to the power measurements, the model, the user-specified offsets, and/or data used by the model to generate the corrections. According to one aspect of the method, the power sensor is an in-line power sensor and has power handing greater than or equal to 1 watt.

According to yet another embodiment of the invention, disclosed is a radio frequency (RF) power sensor having a measurement uncertainty, including: a transmission line; a processor; and a memory communicatively connected to the processor, the memory storing instructions that, when executed by the processor, cause the processor to: adjust a calibration of the power sensor by applying a calibration offset based on: a model of the power sensor, an output of at least one environmental sensor of the power sensor, and an output of at least one operating condition sensor of the power sensor; perform a power measurement of RF power on the transmission line using the power sensor after the adjustment of the calibration, wherein the adjustment of the calibration is performed by the power sensor and permits the power sensor to maintain the measurement uncertainty over time and changing environmental conditions.

According to one aspect of the power sensor, the measurement uncertainty is less than about ±3%. According to a further aspect of the power sensor, the measurement uncertainty is less than about ±1%. According to another aspect of the power sensor, the measurement uncertainty is less than about ±0.5%. According to an additional aspect of the power sensor, the measurement uncertainty is less than about ±0.3%.

According to one aspect of the power sensor, the model uses at least one or more of artificial intelligence, machine learning, neural networks, and/or large data model. According to a further aspect of the power sensor, the environmental sensor monitors at least one environmental condition, wherein the environmental condition includes at least one of temperature, humidity, shock, orientation, and/or vibration. According to another aspect of the power sensor, the calibration offset is a calibration offset applied to a forward power measurement of the power sensor and/or a calibration offset applied to a reflected power measurement of the power sensor.

According to an additional aspect of the power sensor, the operating condition sensor monitors at least one operating condition, wherein the operation condition includes at least one of a total time the power sensor has received external power, a total time the power has been present on the transmission line of the power sensor, a peak amplitude of the power on the transmission line, an average amplitude of the power on the transmission line, a frequency of the power on the transmission line, and/or a number of times a connector of the transmission line has been mated.

According to one aspect of the power sensor, the memory storing instructions that, when executed by the processor, cause the processor to: continuously monitor at least one of the operating conditions and the environmental conditions using the operating conditions sensor and the environmental conditions sensor. According to a further aspect of the memory storing instructions that, when executed by the processor, cause the processor to: use an on-board power source to continuously monitor the operating conditions and the environmental conditions during shipping, handling, and storage of the power sensor. According to another aspect of the power sensor, the on-board power source permits the continuous monitoring of the operating conditions and the environmental conditions, when off-board power is not available. According to an additional aspect of the power sensor, the memory storing instructions that, when executed by the processor, cause the processor to: apply a user-specified offset to the power measurement.

According to one aspect of the power sensor, the memory storing instructions that, when executed by the processor, cause the processor to: send shared data to and receive shared data from other power sensors; and update the model using one or more of the shared data received from the other power sensors, the operating conditions, the environmental conditions, the power measurement, and/or the user-specified offset. According to a further aspect of the power sensor, the shared data includes at least one of calibration data, the corrections applied to the power measurements, the model, the user-specified offsets, and/or data used by the model to generate the corrections. According to another aspect of the power sensor, the power sensor is an in-line power sensor and has power handing greater than or equal to 1 watt.

Advantages of the present invention will become more apparent to those skilled in the art from the following description of the embodiments of the invention which have been shown and described by way of illustration. As will be realized, the invention is capable of other and different embodiments, and its details are capable of modification in various respects.

### BRIEF DESCRIPTION OF THE DRAWINGS

FIG. 1 is an exploded view of a radio frequency (RF) power sensor in accordance with an exemplary embodiment of the invention;

FIG. 2 is a top plan view of the RF power sensor in accordance with an exemplary embodiment of the invention of FIG. 1;

FIG. 3 is a block diagram illustrating the arrangement of the electrical components used in the RF power sensor in accordance with an exemplary embodiment of the invention of FIGS. 1 and 2;

FIG. 4 is a method of using the RF power sensor in accordance with an exemplary embodiment of the invention of FIGS. 1-3; and

FIG. 5 is an additional method of using the RF power sensor in accordance with an exemplary embodiment of the invention of FIGS. 1-3.

It should be noted that all the drawings are diagrammatic and not drawn to scale. Relative dimensions and proportions of parts of these figures have been shown exaggerated or reduced in size for the sake of clarity and convenience in the drawings. The same reference numbers are generally used to refer to corresponding or similar features in the different embodiments. Accordingly, the drawing(s) and description are to be regarded as illustrative in nature and not as restrictive.

### DETAILED DESCRIPTION OF THE INVENTION

Approximating language, as used herein throughout the specification and claims, may be applied to modify any quantitative representation that could permissibly vary without resulting in a change in the basic function to which it is related. Accordingly, a value modified by a term or terms, such as “about”, is not limited to the precise value specified. In at least some instances, the approximating language may correspond to the precision of an instrument for measuring the value. Range limitations may be combined and/or interchanged, and such ranges are identified and include all the sub-ranges stated herein unless context or language indicates otherwise. Other than in the operating examples or where otherwise indicated, all numbers or expressions referring to quantities of ingredients, reaction conditions and the like, used in the specification and the claims, are to be understood as modified in all instances by the term “about”.

“Optional” or “optionally” means that the subsequently described event or circumstance may or may not occur, or that the subsequently identified material may or may not be present, and that the description includes instances where the event or circumstance occurs or where the material is present, and instances where the event or circumstance does not occur or the material is not present.

As used herein, the terms “comprises”, “comprising”, “includes”, “including”, “has”, “having”, or any other variation thereof, are intended to cover a non-exclusive inclusion. For example, a process, method, article or apparatus that comprises a list of elements is not necessarily limited to only those elements, but may include other elements not expressly listed or inherent to such process, method, article, or apparatus.

The singular forms “a”, “an”, and “the” include plural referents unless the context clearly dictates otherwise.

A “processor”, as used herein, processes signals and performs general computing and arithmetic functions. Signals processed by the processor can include digital signals, data signals, computer instructions, processor instructions, messages, a bit, a bit stream, or other means that can be received, transmitted and/or detected. Generally, the processor can be a variety of various processors including multiple single and multicore processors and co-processors and other multiple single and multicore processor and co-processor architectures, including, but not limited to, a microcontroller containing both a processor and memory, programmable logic array (PLA), application specific integrated circuit (ASIC), or any type of device suitable for processing signals, performing general computing, and/or arithmetic functions. The processor can include various modules to execute various functions.

A “memory”, as used herein can include volatile memory and/or nonvolatile memory. Non-volatile memory can include, for example, ROM (read only memory), PROM (programmable read only memory), EPROM (erasable PROM), and EEPROM (electrically erasable PROM). Volatile memory can include, for example, RAM (random access memory), synchronous RAM (SRAM), dynamic RAM (DRAM), synchronous DRAM (SDRAM), double data rate SDRAM (DDRSDRAM), and direct RAM bus RAM (DRRAM). The memory can also include a disk. The memory can store an operating system that controls or allocates resources of a computing device. The memory can also store data for use by the processor.

A “module”, as used herein, includes, but is not limited to, hardware, firmware, software in execution on a machine, and/or combinations of each to perform a function(s) or an action(s), and/or to cause a function or action from another module, method, and/or system. A module can include a software controlled microprocessor, a discrete logic circuit, an analog circuit, a digital circuit, a programmed logic device, a memory device containing executing instructions, and so on.

A “disk”, as used herein can be, for example, a magnetic disk drive, a solid state disk drive, a floppy disk drive, a tape drive, a Zip drive, a flash memory card, and/or a memory stick. Furthermore, the disk can be a CD-ROM (compact disk ROM), a CD recordable drive (CD-R drive), a CD rewritable drive (CD-RW drive), and/or a digital video ROM drive (DVD ROM). The disk can store an operating system and/or program that controls or allocates resources of a computing device.

Some portions of the detailed description that follows are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps (instructions) leading to a desired result. The steps are those requiring physical manipulations of physical quantities. Usually, though not necessarily, these quantities take the form of electrical, magnetic or optical non-transitory signals capable of being stored, transferred, combined, compared and otherwise manipulated. It is convenient at times, principally for reasons of common usage, to refer to these signals as bits, values, elements, symbols, characters, terms, numbers, or the like. Furthermore, it is also convenient at times, to refer to certain arrangements of steps requiring physical manipulations or transformation of physical quantities or representations of physical quantities as modules or code devices, without loss of generality.

However, all of these and similar terms are to be associated with the appropriate physical quantities and are merely convenient labels applied to these quantities. Unless specifically stated otherwise as apparent from the following discussion, it is appreciated that throughout the description, discussions utilizing terms such as “processing” or “computing” or “calculating” or “determining” or “displaying” or “determining” or the like, refer to the action and processes of a computer system, or similar electronic computing device (such as a specific computing machine), that manipulates and transforms data represented as physical (electronic) quantities within the computer system memories or registers or other such information storage, transmission or display devices.

Certain aspects of the embodiments described herein include process steps and instructions described herein in the form of an algorithm. It should be noted that the process steps and instructions of the embodiments could be embodied in software, firmware or hardware, and when embodied in software, could be downloaded to reside on and be operated from different platforms used by a variety of operating systems. The embodiments can also be in a computer program product which can be executed on a computing system.

The embodiments also relates to an apparatus for performing the operations herein. This apparatus can be specially constructed for the purposes, e.g., a specific computer, or it can comprise a general-purpose computer selectively activated or reconfigured by a computer program stored in the computer. Such a computer program can be stored in a non-transitory computer readable storage medium, such as, but is not limited to, any type of disk including floppy disks, optical disks, CD-ROMs, magnetic-optical disks, read-only memories (ROMs), random access memories (RAMs), EPROMS, EEPROMs, magnetic or optical cards, ASICs, or any type of media suitable for storing electronic instructions, and each electrically connected to a computer system bus. Furthermore, the computers referred to in the specification can include a single processor or can be architectures employing multiple processor designs for increased computing capability.

The algorithms and displays presented herein are not inherently related to any particular computer or other apparatus. Various general-purpose systems can also be used with programs in accordance with the teachings herein, or it can prove convenient to construct more specialized apparatus to perform the method steps. The structure for a variety of these systems will appear from the description below. In addition, the embodiments are not described with reference to any particular programming language. It will be appreciated that a variety of programming languages can be used to implement the teachings of the embodiments as described herein, and any references below to specific languages are provided for disclosure of enablement and best mode of the embodiments.

In addition, the language used in the specification has been principally selected for readability and instructional purposes, and may not have been selected to delineate or circumscribe the inventive subject matter. Accordingly, the disclosure of the embodiments is intended to be illustrative, but not limiting, of the scope of the embodiments, which is set forth in the claims.

The present state of the art in-line RF power measurement accuracy is around ±0.5%. This limitation is due to the combination of a variety of sources of uncertainty, including, but not limited to, the calibration standard, temperature, humidity, mechanical stability, frequency response, dynamic non-linearities, noise, connector wear, and aging. Some of these uncertainties are consistent throughout the life of the sensor, but others change with time, causing the sensor accuracy to exceed its specified limits. This is one of the main reasons for the regular recalibration of RF power sensors, often every 6 or 12 months.

Calibration approaches for currently available in-line RF power sensors call for the removal of the power sensor from the RF power delivery path so that it may be returned to the factory for calibration. The major issue associated with this process is that the RF system must be shut down while the in-line power sensor is removed from the system and temporarily replaced with either a spare power sensor or a temporary transmission line section. Furthermore, the removal and replacement of the power sensor with a spare power sensor opens the door for process shifts due to the difference in power measurement between the two sensors. Due to the inherent inconvenience, opportunity for process shifts, and loss of revenue associated with an RF system shut down and equipment removal, most power sensors are either calibrated very infrequently or not calibrated altogether. This inconvenience is also present for RF power sensors that are not installed in an RF system, but used in a calibration or verification context, where RF power is only used when the calibration or verification if performed.

Calibration date and the next recommended calibration date are typically marked on the power sensor by means of a physical calibration label and/or indicated on the documents that accompany a sensor calibration. Sometimes this information may also be stored in power sensor memory, but given that power sensors in the semiconductor market are typically used as standalone devices without any network access, they have no knowledge of the current calendar date. As such, the sensor itself has no way of knowing whether it is approaching or has passed the next recommended calibration date and can give no warning to the user. This information must be tracked externally by the user and/or their metrology group, running the risk that a power sensor is unknowingly out of calibration.

In view of these limitations, a need exists for a RF power sensor that can achieve a power measurement accuracy of better than ±0.5%, maintain that accuracy over time, reduce the need for frequent recalibration, and inform the user whether recalibration is required if an out-of-calibration condition is detected.

The present invention satisfies the needs described above and affords other features and advantages heretofore not obtainable. Referring more particularly to the drawings, there is shown an embodiment of the invention, self-monitoring high accuracy radio frequency power sensor.

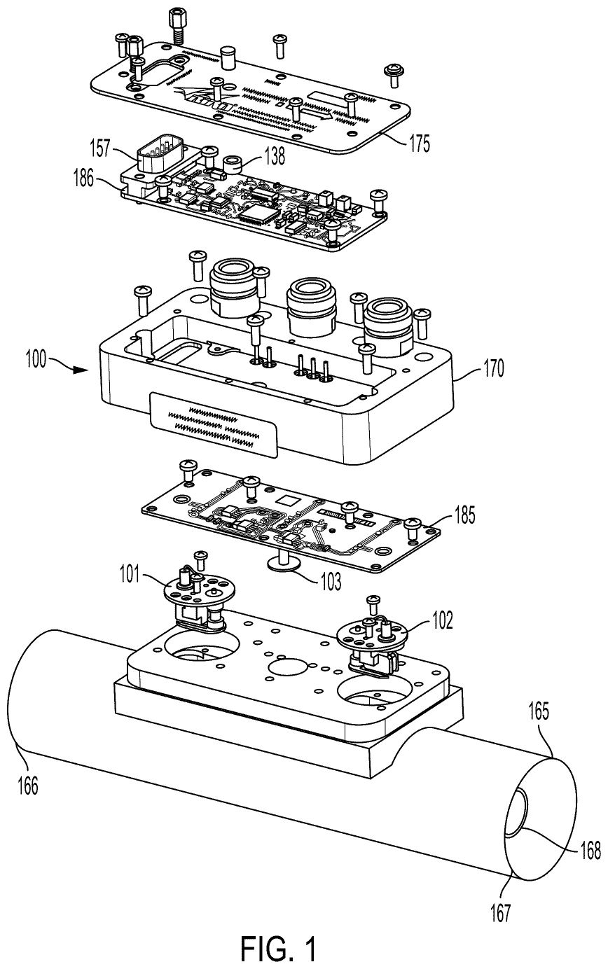

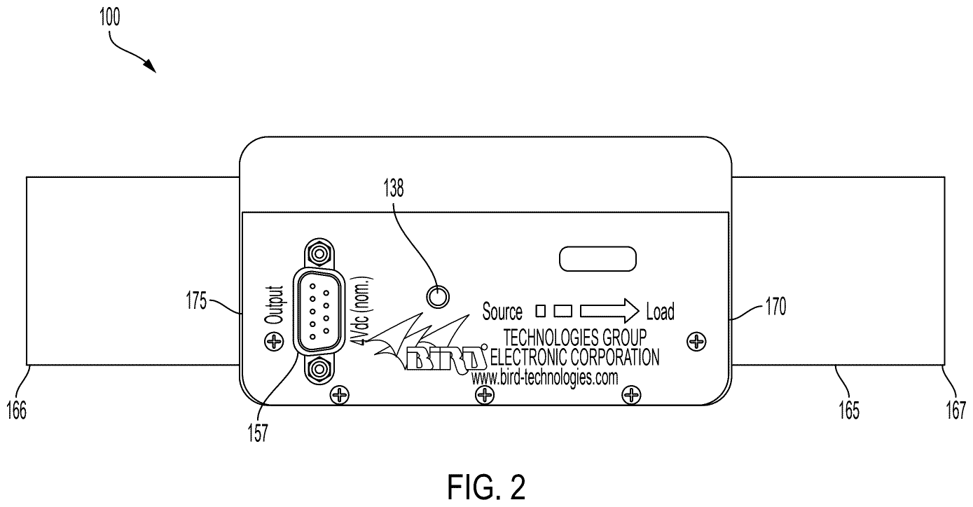

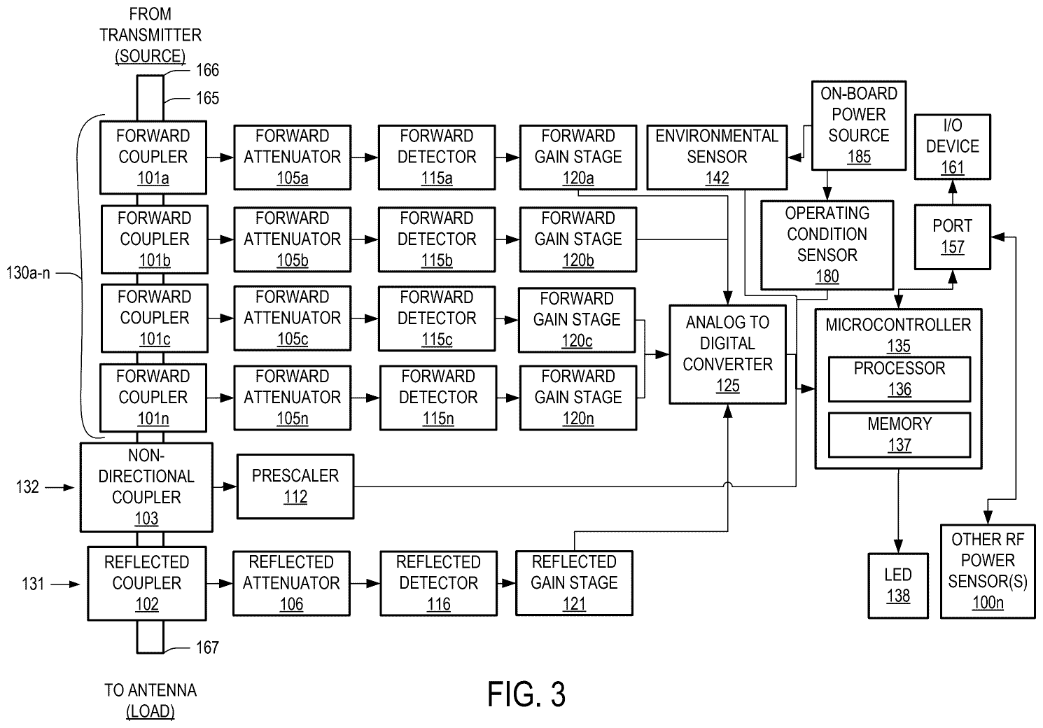

Referring to FIGS. 1-3, a self-monitoring high accuracy radio frequency (RF) power sensor 100 a measurement uncertainty of less than about ±0.3% that can adjust its own calibration to maintain its measurement uncertainty. In an exemplary embodiment, power sensor 100 can adjust calibration based on environmental and/or operating conditions, which may be continuously monitored. In an exemplary embodiment, power sensor 100 may be a thru-line power sensor. Further, in exemplary embodiments, power sensor 100 may be capable of measuring an RF power level greater than or equal to about 1 watt (power handling capability of greater than or equal to about 1 watt). Power sensor 100 comprises a transmission line section 165 having a body 170 is fastened to the transmission line section 165. Forward directional couplers 101a-n, reflected directional coupler 102, and non-directional coupler 103 are located inside the body 170. In some exemplary embodiments, the body 170 may be rectangular and may have a cover 175. In some exemplary embodiments, body 170 may be a shape other than rectangular and may be dictated by the positioning of the couplers contained therein along the transmission line 165. In an exemplary embodiment, non-directional coupler 103 is mounted on a RF board 185, while the RF board 185 is placed on top of forward and reflected couplers 101a-n and 102. All of the couplers 101a-n, 102, and 103 interface with the RF board. Some exemplary embodiments of power sensor 100 may have three forward couplers 101a-c. However, it is contemplated that other exemplary embodiments of power sensor 100 may have more or less forward couplers 101a-n, with “n” being the letter in the alphabet equivalent to the number of forward couplers present.

A logic board 186 is placed on top of and interfaces with the RF board 185. The logic board 186 has a port 157 and LED 138. The port 157 may be a USB port, Ethernet port, or any other suitable port for communicating with the logic board 186 of power sensor 100. The port 157 is accessible through the cover 175 and LED 138 is visible through the cover 175. The port 157 provides an output of the various measurements of power sensor 100 to a user via I/O device 161. I/O device 161 can include, but is not limited to, a screen, computer, mobile device, or a server. I/O device 161 can be hardwired to port 157 or wirelessly connected to port 157, such as, but not limited to, WiFi or Bluetooth, or communicate via a combination of wireless and wired networks.

In some exemplary embodiments, power sensor 100 comprises a transmission line section 165 with a source end 166 and a load end 167. A body 170 is fastened to the transmission line 165. The body 170 can have a cover 175. A port 157 is accessible through the cover 175 and an LED 138 is visible through the cover 175.

In operation, radio frequency (RF) voltage samples of the transmission line power are made available by the forward directional coupler 101a-c and reflected directional coupler 102. A non-directional voltage coupler 103 is used by the microcontroller 135 to measure the RF frequency of the RF signal. In some exemplary embodiments, the couplers 101a-c and 102 may be part number 7006A216 from Bird Technologies Group. The samples of the main transmission line power provided by the forward couplers 101a-c and reflected coupler 102 are approximately −55 dB from the main transmission line power. The transmission line 165 has a source end 166 and a load end 167. The source end 166 and the load end have connectors, namely the source end 166 has a source end connector 166a and load end 167 has a load end connector 167a.

The prescaler 112 measures the frequency of the sample of the main transmission line power provided by the non-directional coupler 103 and divides the frequency down to a digital representation of a lower frequency that can be measured by the microcontroller 135. The output of the prescaler 112 is provided to the microcontroller 135. In other exemplary embodiments, the prescaler 112 outputs an analog signal to the analog to digital converter 125. The non-directional coupler 103 and prescaler, 112 form the non-directional circuit 132.

The RF voltage samples from the forward directional couplers 101a-c are routed to the forward power attenuators 105a-c respectively, while RF voltage samples from the reflected directional coupler 102 are routed to the reflected power attenuator 106. The number of forward power attenuators 105a-n correspond with the number of forward couplers 101a-n present in the power sensor 100, with “n” being the letter in the alphabet equivalent to the number of forward couplers present. The forward power attenuators 105a-c and reflected power attenuator 106 are resistive attenuators for setting the appropriate voltage levels for the forward detectors 115a-c and reflected detector 116. In an exemplary embodiment, the forward power attenuators 105a-c and reflected power attenuator 106 are contained in an RF circuit assembly from Bird Technologies Group.

The forward power attenuator 105a-c outputs a RF voltage to the forward detectors 115a-c respectively. The reflected power attenuator 106 outputs a RF voltage to the reflected detector 116.

The forward detectors 115a-c and reflected detector 116 use diodes to convert the RF voltages into small direct current (DC) voltages. The number of forward detectors 115a-n correspond with the number of forward couplers 101a-n present in power sensor 100, with “n” being the letter in the alphabet equivalent to the number of forward couplers 101 present.

The output of the forward detector 115a-c is amplified by a forward gain stage 120a-c respectively and the output of the reflected detector 116 is amplified by a reflected gain stage 121. The forward gain stages 120a-c and reflected gain stage 121 are precision operational amplifiers with very high input impedances to not load down the diodes. The number of forward gain stages 120a-n correspond with the number of forward couplers 101a-n present in power sensor 100, with “n” being the letter in the alphabet equivalent to the number of forward couplers 101 present.

In an exemplary embodiment, the output of the forward gain stages 120a-c and reflected gain stage 121 is approximately 2 volts DC at the full scale rating of the instrument.

The power sensor 100 may also have forward coupler circuits 130a-c. The components of the forward coupler circuits 130a-c may include, but are not limited to, forward couplers 101a-c, forward attenuators 105a-c, forward detectors 115a-c, and forward gain stages 120a-c. The number of forward coupler circuits 120a-n correspond with the number of forward couplers 101a-n present in power sensor 100, with “n” being the letter in the alphabet equivalent to the number of forward couplers 101 present.

In exemplary embodiments where an individual analog to digital converter 125 is used for each forward coupler circuit 130a-n, then the forward coupler circuits 130a-n may also include the analog to digital converters 125a-n and may provide outputs directly to microcontroller 135. In exemplary embodiments where an individual analog to digital converter 125 is not used for each forward coupler circuit 130a-n, then the outputs of the individual forward coupler circuits 130a-n may be provided to one or more analog to digital converters 125, which will then digitize the outputs of the forward coupler circuits 130a-n and provide digitized representations of the outputs to the microcontroller 135. Forward gain stages 120a-c and reflected gain stage 121 output the amplified DC voltage to an analog to digital converter 125.

As can be seen, the multiple forward directional coupler circuits 130a-n, with each circuit having independent (non-shared) components, it can be seen that power sensor 100 uses the principle of error reduction by cross-correlation, such as, that the uncertainty of a measurement can be reduced by the square root of N, where N is the number of uncorrelated measurements of the same information. By using N uncorrelated measurements, the uncertainty of the power sensor 100 can be reduced. Thus, in an exemplary embodiment, power sensor 100 achieves this cross correlation by using two or more independent multiple measurements of RF power on the transmission line 165, such as the forward power measurements acquired by forward directional coupler circuits 130a-n, with each circuit having independent components to achieve the highest degree of independence. The independent components may be include, but are not limited to, forward coupler 101a-n, forward attenuator 105a-n, forward detector 115a-n, forward gain stage 120a-n, and optionally analog-to digital converter 125a-n.

The power sensor 100 can also include one or more environmental sensors 142 for sensing (obtaining measurement(s) of) the environmental conditions of power sensor 100 that can impact the uncertainty of the measurement of power sensor 100, which will permit power sensor 100 to adjust its own calibration to maintain its measurement uncertainty in changing environmental conditions. In an exemplary embodiment, the outputs of these environmental sensors 142 may be correlated with changes to the forward and reflected measurements of power sensor 100, such as the outputs of the forward directional coupler circuits 101a-n and reflected directional coupler circuit 102, due to the environmental conditions and can be used to correct (offset) the forward and reflected power measurements (outputs of the forward directional coupler circuits 101a-n and reflected directional coupler circuit 102).

Such environmental conditions sensed (measured) by environmental sensor 142 may include, but are not limited to, temperature, humidity, shock, orientation, and vibration. In some exemplary embodiments of power sensor 100, a single environmental sensor 142 may sense (measure) all of the applicable environmental conditions. In other exemplary embodiments of power sensor 100, more than one environmental sensor 142 may be used to sense (measure) all of the applicable environmental conditions. Environmental condition measurements taken by an environmental sensor 142 having a digital output may be directly outputted to microcontroller 135. Further, environmental condition measurements taken by an environmental sensor 142 having an analog output may be sent to analog to digital converter 125.

Further, in some exemplary embodiments, power sensor 100 may also include one or more operation condition sensors 180 for sensing (obtaining measurement(s) of) the operating conditions of power sensor 100, which will permit power sensor 100 to adjust its own calibration to maintain its measurement uncertainty in changing operating conditions. Such operating conditions sensed (measured) by operating condition sensors 180 may include, but are not limited to, total time the power sensor 100 is powered (receiving external power, such as through port 157), the total time that RF power is present on transmission line 165, the amplitude of the RF power on transmission line 165 (such as peak amplitude and average amplitude), the frequency of the RF power on transmission line 165, and the number of connector mating cycles with power sensor 100 (the number of times the connectors of transmission line 165 have been mated with a source transmission line and a load transmission line carrying the signal to be measured). Such operating conditions may lead to aging and drift mechanisms that may increase the uncertainty of the measurements of power sensor 100, unless corrected for. In some exemplary embodiments of power sensor 100, a single operation condition sensor 180 may sense (measure) all of the applicable operation conditions. In other exemplary embodiments of power sensor 100, more than one operation condition sensor 180 may be used to sense (measure) all of the applicable operating conditions.

Further, it is contemplated that an operating conditions sensor 180 may be any sensor or circuit in power sensor 100 that may provide measurements relevant to operating conditions. Thus, in an exemplary embodiment of power sensor 100, such sensors or circuits of power sensor 100 may include, but are not limited to, forward coupler 101a-n, forward directional coupler circuit 130a-n, reflected coupler 102, reflected directional coupler circuit 131, non-directional coupler 103, and non-directional circuit 132.

In an exemplary embodiment, the outputs of these operating conditions sensors 180 may be correlated with changes to the forward and reflected measurements of power sensor 100, such as the outputs of the forward directional coupler circuits 101a-n and reflected directional coupler circuit 102, due to the operating conditions and can be used to correct (offset) the forward and reflected power measurements (offset the outputs of the forward directional coupler circuits 101a-n and reflected directional coupler circuit 102).

Operating conditions measurements taken by an operating conditions sensor 180 having a digital output may be directly outputted to microcontroller 135. Further, operating conditions measurements taken by an environmental sensor 142 having a digital output may be directly outputted to microcontroller 135.

Further, some exemplary embodiments of power sensor 100 may have an on-board power source 185 that provides power to the environmental sensors 142 and operating condition sensors 180, and various other circuitry for processing and saving the outputs of the environmental sensors 142 and operating condition sensors 180. This permits for the environmental conditions and operating conditions of power sensor 100 to be monitored at all times regardless of the status of off-board power. Thus, the environmental conditions and operating conditions of power sensor 100 may be continuously monitored even when the power sensor 100 is being shipped to or from the factory, being handled, and/or in storage.

The analog to digital converter 125 digitizes the signals from the forward gain stage outputs 120a-c, reflected gain stage output 121, and sends the digital signals to the microcontroller 135. As was stated above, since components in the power sensor 100 can vary based on the environmental conditions and operating conditions the signals from the forward gain stage outputs 120a-c and reflected gain stage output 121 may be corrected to account for these environmental conditions and operating conditions, as is described below.

The microcontroller 135 applies offsets (corrections) to the forward power measurements (outputs) of the forward directional coupler circuits 101a-n and reflected power measurements (outputs) of the reflected directional coupler circuit 102. The applied calibration offsets use the measurements of the one or more operating condition sensors 180 and measurements of the one or more environmental sensors 142 correlated through a model. The model may incorporate one or more of artificial intelligence, machine learning, neural networks, and the large data model of the power sensor 100. The model may encompass (model) the entire power sensor 100 as a whole and/or individual components of power sensor 100.

For example, in an exemplary embodiment of power sensor 100, the model stored in microcontroller 135 may correct (offset) for the effects of thermally and humidity induced drift in the power sensor 100, such as, but not limited to, forward and reflected detectors 115a-c and 116.

In some exemplary embodiments of power sensor 100, the calibration offsets (corrections) applied to the forward power measurements and reflected power measurement by microcontroller 135 may also include user-specified measurement offsets for the outputs of the forward measurement circuits 101a-n and reflected measurement circuit 102. These user-specified offsets may give the user the ability to offset the power measurements for a particular application of power sensor 100. These user-specified offsets (parameters and parameter values) may be provided to the power sensor and model via I/O device 161.

Similarly, the uncertainty of the outputs of some power measurement components of the power sensor 100 may vary based on frequency. Therefore, the model in microcontroller 135 may use the output of the prescaler 112 to correct for (reduce) the effects of frequency on the uncertainty of the power sensor 100. The power measurement components of the power sensor 100 that may vary based on frequency include, can include, but are not limited to, one or more of the components in the forward coupler circuits 130a-n, which may include, but are not limited to, forward couplers 101a-n. The power measurement components of the power sensor 100 of which uncertainty may vary based on frequency can also include, but are not limited to, any components of the non-directional coupler circuit 132, such as, but not limited to non-directional coupler 103. Further, the power measurement components of the power sensor 100 of which uncertainty may vary based on frequency may also include any component located in the signal path between a coupler and the microcontroller 135. The coupler can be one or more of forward couplers 101a-n, reflected coupler 102, and/or non-directional coupler 103.

In some embodiments of power sensor 100, the microcontroller 135 may provide an output to the LED 138, which may provide a visual indication of the calibration status. In an exemplary embodiment, the LED 138 states may be as follows: the LED 138 turns off when the power sensor 100 is within calibration; and LED 138 blinks if the power sensor 100 needs to be calibrated (not in calibration).

The main task of the microcontroller 135 is to linearize the diode detectors output, provide some digital averaging of the data received from the analog to digital converter 125, and power measurements, and perform corrections for the environmental conditions and operation conditions.

In an exemplary embodiment, microcontroller 135 may have a processor 136 and memory 137. The processor 136 may be used to store in memory 137 forward power measurements obtained from the forward couplers 101a-n of the forward coupler circuits 130a-n, reflected power measurements obtained from the reflected coupler 102 of the reflected coupler circuit 131, frequency measurements obtained by the non-directional coupler 103 of the non-directional coupler circuit 132, operation condition measurements obtained by operation condition sensors 180, and environmental condition measurements obtained by environmental sensors 142.

In some exemplary embodiments of power sensor 100, the power sensor 100 may share data with one or more other power sensors 100n. This shared data may include calibration data (calibration offsets applied to the forward power measurements of forward directional coupler circuits 101a-n and/or calibration offsets applied to the reflected power measurements of reflected directional coupler circuit 102), the model used to calculate the corrections (model parameters and values for the parameters), and the user-specified offsets applied to the forward and reflected power measurements. The shared data may also include the underlying data used by the model to generate the calibration offsets applied to the forward power measurements and reflected power measurements.

Further, in other exemplary embodiments, it is contemplated that a user can replace microcontroller 135 with suitable stand along processor 136 and memory 137, application specific integrated circuit, field programmable gate array, or discrete circuitry. It is also contemplated that the functions of the forward gain stages 120a-c and reflected gain stage 121, analog to digital converter 125 and digital to analog converter 145 can be replicated or replaced using one or more of suitable microcontroller, processor and memory, application specific integrated circuit, field programmable gate array, or discrete circuitry.

Additionally, the various types of couplers, sensors, and associated circuitry present in the power sensor 100, such as, but not limited to, the forward couplers 101a-n, reflected coupler 102, non-directional coupler 103, operating condition sensor 180, and environmental sensor 142, provide additional degrees of independence between measurements.

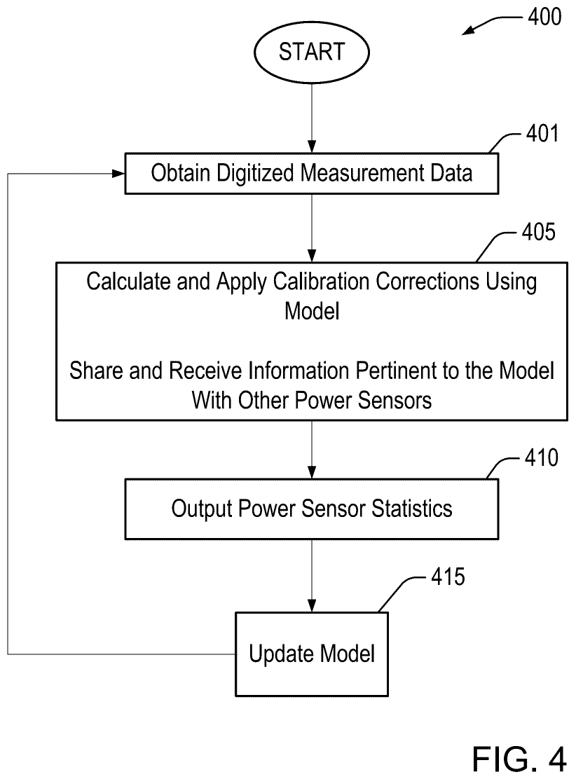

Turning to FIG. 4, a method 400 of operating power sensor 100 is shown in the form of an algorithm that is stored in memory 137 and executed by processor 136 of microcontroller 135 in power sensor 100 to self-calibrate the power sensor 100, such as the forward couplers 101a-n and/or reflected coupler 102. It is contemplated that the same method (algorithm) can also be used to calibrate more components along the measurement chain, such as, but not limited to, the components of the forward coupler circuits 130a-c, such as forward couplers 101a-c, forward attenuators 105a-c, forward detectors 115a-c, and forward gain stages 120a-c. In exemplary embodiments where an individual analog to digital converter 125 is used for each forward coupler circuit 130a-c, then the forward coupler circuits 130a-c can also include the analog to digital converters.

It is contemplated that the algorithm/method 400 of FIG. 4 may be implemented using one or more of artificial intelligence, machine learning, neural networks, and/or large data models.

To self-calibrate the power sensor 100, in 401, the microcontroller 135 receives (obtains) digitized measurement data and stores the data in memory 137. The digitized measurement data can included digitized forward power measurement data from the analog to digital converter 125. The data is separated and stored in memory 137 for each forward coupler 101a-n of forward coupler circuits 130a-n. In some exemplary embodiments, there can be three forward coupler circuits 130a-c, with each circuit having a forward coupler 101a-c. It is contemplated that other exemplary embodiments of power sensor 100 can have more or less than three forward coupler circuits 130a-n and corresponding forward couplers a-n.

The digitized measurement data can also include digitized reflected power measurement data from the reflected coupler 102 of the reflected coupler circuit 131 (digitized reflected power measurement data) and digitized frequency measurement data corresponding to the frequency of the signal being measured on transmission line 165 from the non-directional coupler 103 and frequency downconverted by the prescaler 112 of the non-directional circuit 132. The digitized measurement data can also include digitized operating condition data from the operating condition sensor 180 (digitized operating condition sensor 180 output), and digitized data from the environmental sensor 142 (digitized environmental sensor 142 output).

Following the obtaining of the digitized measurement data in 401, in 405, the digitized forward power measurement data is then retrieved from memory 137, and calibration offsets are applied to the digitized forward power measurement data using processor 136 (raw forward power measurements), thereby resulting in calibrated forward power measurements. In some exemplary embodiments of power sensor 100, calibration offsets may also be applied to the digitized reflected power measurement data retrieved from memory 137 (raw reflected power measurements), thereby resulting in calibrated reflected power measurements. The calibrated forward power measurements and calibrated reflected power measurements are stored in memory 137.

The calibration offsets may be calculated by processor 136 using, the model of power sensor 100 stored in memory 137 and the digitized measurement data, such as, but not limited to, the output from the digitized operation condition sensor(s) 180 and environmental sensor(s) 142. It is also contemplated that in some embodiments, the calibration offsets may be calculated using one or more of, artificial intelligence, machine learning, neural networks, and/or large data models. The calibration offsets can also include user-specified offsets. These user-specified offsets (parameters and parameter values) may be provided to the power sensor and model via I/O device 161. The parameters used in by the model of power sensor 100 to calculate the calibration offsets may include, but are not limited to, corrections for the environmental conditions and operation conditions that may increase the uncertainty of the measurements of power sensor 100.

Such environmental and operation conditions may include, but are not limited to, temperature, humidity, shock, orientation, vibration, aging and drift mechanisms, total time the power sensor 100 is powered (receiving external power, such as through port 157), the total time that RF power is present on transmission line 165, the amplitude of the RF power on transmission line 165 (such as peak amplitude and average amplitude), the frequency of the RF power on transmission line 165, and the number of connector mating cycles with power sensor 100 (the number of times the connectors of transmission line 165 have been mated with a source transmission line and a load transmission line carrying the signal to be measured).

The power sensor 100 may also send to other sensors 100n and receive from other sensors 100n information pertinent to the model of power sensor 100. For example, the power sensor 100 may send and receive (share) information with one or more other power sensors 100n pertinent to the calibration of the model of power sensor 100. Such pertinent information may include, but is not limited to, calibration offsets, models (one or more of artificial intelligence, machine learning, neural networks, and large data models, including parameters and parameter values), and user-specified offsets.

In an exemplary embodiment, power sensor 100 may share the above information with one or more other power sensors 100n via a wired and/or wireless communication. The wired or wireless communication may be through port 157.

This use of the model of power sensor 100 and sharing of information between power sensor 100 and other power sensors 100n permit the power sensor 100 to adjust its calibration data (calibration offsets) in order to maintain the specified uncertainty of the power sensor 100 over a wide range of environmental conditions and customer use cases.

As was stated above, once the calibration offsets are applied to the digitized forward power measurement data and digitized reflected power measurement data by processor 136, the calibrated forward power measurement data for each individual forward coupler circuit 130a-n is individually calculated and stored in memory 137 by processor 136. Further, calibrated reflected power measurement value is then stored in memory 137 by processor 136. Next, an aggregate average forward power measurement is calculated by processor 136 by averaging together the calibrated forward power measurement data for each individual forward coupler circuit 130a-n. This aggregate average forward power measurement value is stored in memory 137 by processor 136.

Following 405, the method 400 proceeds to 410, where the power sensor statistics are outputted to the user. The power sensor statistics may include one or both of the aggregate average forward power measurement value and the calibrated reflected power measurement value. Further in 410, power sensor statistics may be any other information saved in memory 137 can be outputted to a user, such as via port 157 and/or via I/O device 161. Such information may include, but is not limited to, digitized measurement data, calibration corrections, and information regarding the model.

Following 410, in 415, the model of power sensor 100 is updated, such as by updating the parameters and parameter values of the model. The model may incorporate one or more of artificial intelligence, machine learning, neural networks, and/or large data models. The model may be updated based on a variety of information, such as, but not limited to, one or more of the information received from other power sensors 100n in 405, the digitized measurement data obtained in 401, and/or the calculations performed in 405, including, but not limited to, the aggregate average forward power measurement value and the calibrated reflected power measurement value, user-specified offsets, and environmental and operation conditions. Once the model is updated in 415, it is saved in memory 137.

Following the updating and saving of the model in 415, the algorithm proceeds back to 401. The algorithm 400 may be implemented using one or more of artificial intelligence, machine learning, neural networks, and/or large data models.

Thus, as can be seen in algorithm 400, the calibration of the power sensor 100 having a measurement uncertainty may be adjusted by applying a calibration offset (correction) to the forward power measurement (digitized forward power measurement data) and/or reflected power measurement (digitized reflected power measurement data). The calibration offset may be based on a model of the power sensor 100, an output of at least one environmental sensor 142, and an output of at least one operating condition sensor 180. The power sensor 100 may then perform a power measurement of RF power on the transmission line 165 using the power sensor 100 after the adjustment (offset) of the calibration of the power sensor 100. The adjustment of the calibration of the power sensor 100 is performed by the power sensor 100 and permits the power sensor 100 to maintain the measurement uncertainty over time and changing environmental conditions.

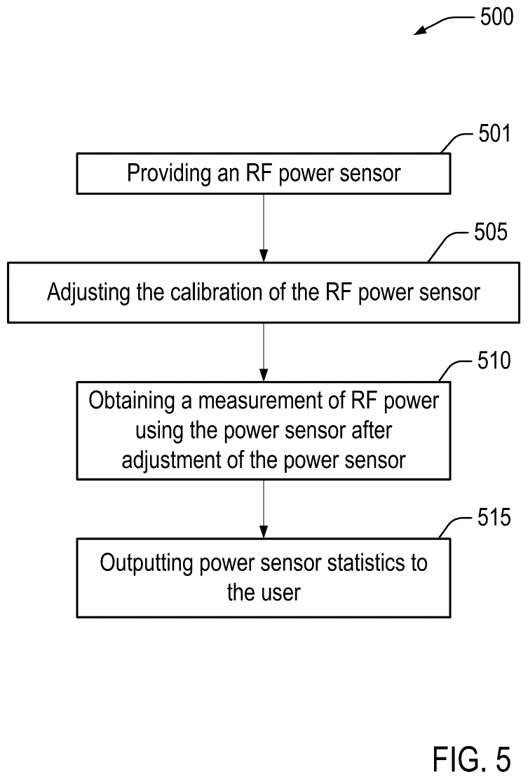

FIG. 5 is another method 500 of using the power sensor 100 in accordance with an exemplary embodiment of the invention of FIGS. 1-3. In 501, a power sensor 100 is provided having a transmission line 165 and a measurement uncertainty. In 505, the calibration of the power sensor 100 is adjusted by applying a calibration offset. The calibration offset may be based on a model of the power sensor 100, an output of at least one environmental sensor 142 of the power sensor 100, and an output of at least one operating condition sensor 180 of the power sensor 100. In 510, a measurement of RF power on said transmission line 165 is made (obtained) using the power sensor 100 after the adjustment of the calibration of the power sensor 100. The adjustment of the calibration (offset) is performed by said power sensor 100 and permits the power sensor 100 to maintain the measurement uncertainty of the power sensor 100 over time and changing environmental conditions. In 515, power sensor statistics of power sensor 100 are outputted to the user.

While this invention has been described with respect to particular embodiments thereof, it is apparent that numerous other forms and modifications of this invention will be obvious to those skilled in the art. The appended claims and this invention generally should be construed to cover all such obvious forms and modifications which are within the true spirit and scope of the present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as critical, required, or essential features or elements of any or all the claims. As used herein, the terms “comprises, “comprising,” or any other variation thereof, are intended to cover a non-exclusive inclusion, such that a process, method, article, or apparatus that comprises a list of elements does not include only those elements, but may include other elements not expressly listed or inherent to such process, method, article, or apparatus. Further, no element described herein is required for the practice of the invention unless expressly described as “essential” or “critical.” While this invention has been described in conjunction with the specific embodiments described above, it is evident that many alternatives, combinations, modifications and variations are apparent to those skilled in the art. Accordingly, the preferred embodiments of this invention, as set forth above are intended to be illustrative only, and not in a limiting sense. Various changes and combinations can be made without departing from the spirit and scope of this invention. Combinations of the above embodiments and other embodiments will be apparent to those of skill in the art upon studying the above description and are intended to be embraced therein. Therefore, the scope of the present invention is defined by the appended claims, and all devices, processes, and methods that come within the meaning of the claims, either literally or by equivalence, are intended to be embraced therein.

What is claimed is:

1. A radio frequency (RF) power sensor having the ability to adjust its own calibration.

2. The power sensor of claim 1, wherein said power sensor adjusts its own calibration to maintain a measurement uncertainty of less than about ±3% of power on a transmission line of said power sensor.

3. The power sensor of claim 1, wherein said power sensor adjusts its own calibration to maintain a measurement uncertainty of less than about ±1% of power on a transmission line of said power sensor.

4. The power sensor of claim 1, wherein said power sensor adjusts its own calibration to maintain a measurement uncertainty of less than about ±0.5% of power on a transmission line of said power sensor.

5. The power sensor of claim 1, wherein said power sensor adjusts its own calibration to maintain a measurement uncertainty of less than about ±0.3% of power on a transmission line of said power sensor.

6. The power sensor of claim 1, wherein said power sensor uses a model of said power sensor to adjust its own calibration by applying at least one calibration offset, based on correlations between a power measurement of said power sensor and at least one of an environmental condition of said power sensor and/or an operating condition of said power sensor.

7. The power sensor of claim 6, wherein said model uses at least one or more of artificial intelligence, machine learning, neural networks, and/or large data model.

8. The power sensor of claim 6, wherein said environmental condition of said power sensor includes at least one or more of temperature, humidity, shock, orientation, and/or vibration; and/or
wherein said calibration offset is a calibration offset applied to a forward power measurement of said power sensor and/or a calibration offset applied to a reflected power measurement of said power sensor.

9. The power sensor of claim 6, wherein said operating condition of said power sensor includes at least one or more of a total time said power sensor has received external power, a total time said power has been present on said transmission line of said power sensor, a peak amplitude of said power on said transmission line, an average amplitude of said power on said transmission line, a frequency of said power on said transmission line, and/or a number of times a connector of said transmission line has been mated.

10. The power sensor of claim 6, wherein one or both of said operating conditions and said environmental conditions are continuously monitored.

11. The power sensor of claim 10, wherein said power sensor further comprises an on-board power source that permits a continuous monitoring of said operating conditions and said environmental conditions during shipping, handling, and storage of said power sensor.

12. The power sensor of claim 11, wherein said on-board power source permits said continuous monitoring of said operating conditions and said environmental conditions, when off-board power is not available.

13. The power sensor of claim 6, wherein said calibration is adjusted by applying one or more calibration offsets to said power measurement of said power sensor, wherein said calibration offsets includes one or more user-specified offsets.

14. The power sensor claim 6, wherein said power sensor sends shared data to and receives shared data from other power sensors, and uses said shared data received from other power sensors to update said model.

15. The power sensor of claim 14, wherein said shared data includes at least one of calibration data, said calibration offsets applied to said power measurements, said model, said user-specified offsets, and/or data used by said model to generate said calibration offsets.

16. The power sensor claim 1, wherein said power sensor is an in-line power sensor and has power handing greater than or equal to 1 watt.

17.-31. (canceled)

32. An radio frequency (RF) power sensor having a measurement uncertainty comprising:
a transmission line;
a processor;
a memory communicatively connected to said processor, the memory storing instructions that, when executed by said processor, cause said processor to:
adjust a calibration of said power sensor by applying a calibration offset based on:
a model of said power sensor,
an output of at least one environmental sensor of said power sensor, and
an output of at least one operating condition sensor of said power sensor;
perform a power measurement of RF power on said transmission line using said power sensor after said adjustment of said calibration,
wherein said adjustment of said calibration is performed by said power sensor and permits said power sensor to maintain said measurement uncertainty over time and changing environmental conditions.

33. The power sensor of claim 32, wherein said measurement uncertainty is less than about ±3%.

34. The power sensor of claim 32, wherein said measurement uncertainty is less than about ±1%.

35. The power sensor of claim 32, wherein said measurement uncertainty is less than about ±0.5%, or
less than about ±0.3%.

36. (canceled)

37. The power sensor of claim 32, wherein said model uses at least one or more of artificial intelligence, machine learning, neural networks, and/or large data model.

38. The power sensor of claim 32, wherein said environmental sensor monitors at least one environmental condition, wherein said environmental condition includes at least one of temperature, humidity, shock, orientation, and/or vibration; and/or
wherein said calibration offset is a calibration offset applied to a forward power measurement of said power sensor and/or a calibration offset applied to a reflected power measurement of said power sensor.

39. The power sensor of claim 32, wherein said operating condition sensor monitors at least one operating condition, wherein said operation condition includes at least one of a total time said power sensor has received external power, a total time said power has been present on said transmission line of said power sensor, a peak amplitude of said power on said transmission line, an average amplitude of said power on said transmission line, a frequency of said power on said transmission line, and/or a number of times a connector of said transmission line has been mated.

40. The power sensor of claim 32, the memory storing instructions that, when executed by the processor, cause the processor to:
continuously monitor at least one of said operating conditions and said environmental conditions using said operating conditions sensor and said environmental conditions sensor.

41. The power sensor of claim 40, the memory storing instructions that, when executed by the processor, cause the processor to:
use an on-board power source to continuously monitor said operating conditions and said environmental conditions during shipping, handling, and storage of said power sensor.

42. The power sensor of claim 41, wherein said on-board power source permits said continuous monitoring of said operating conditions and said environmental conditions, when off-board power is not available.

43. The power sensor of claim 32, the memory storing instructions that, when executed by the processor, cause the processor to:
apply a user-specified offset to said power measurement.

44. The power sensor of claim 32, the memory storing instructions that, when executed by the processor, cause the processor to:
send shared data to and receive shared data from other power sensors; and
update said model using one or more of said shared data received from said other power sensors, said operating conditions, said environmental conditions, said power measurement, and/or said user-specified offset.

45. The power sensor of claim 44, wherein said shared data includes at least one of calibration data, said corrections applied to said power measurements, said model, said user-specified offsets, and/or data used by said model to generate said corrections.

46. The power sensor of claim 32, wherein said power sensor is an in-line power sensor and has power handing greater than or equal to 1 watt.
